(19) United States
(12) Patent Application Publication
(10) Pub. No.: US 2020/0381623 A1
(43) Pub. Date: Dec. 3, 2020

(54) METHODS OF FORMING SILICON NITRIDE ENCAPSULATION LAYERS

(71) Applicant: Applied Materials, Inc., Santa Clara, CA (US)

(72) Inventors: Bo QI, San Jose, CA (US); Abhijit B. MALLICK, Fremont, CA (US)

(21) Appl. No.: 16/814,765

(22) Filed: Mar. 10, 2020

Related U.S. Application Data
(60) Provisional application No. 62/855,597, filed on May 31, 2019.

(51) Int. Cl. H01L 45/00; H01L 27/24; C23C 16/34; C23C 16/455

(52) U.S. Cl. CPC H01L 45/16; H01L 27/2427; C23C 16/345; H01L 45/141; H01L 45/06; H01L 45/1233; C23C 16/45542

(57) ABSTRACT

Embodiments described herein generally relate to methods of processing a substrate comprising positioning a substrate in a processing volume of a processing chamber. The substrate includes a patterned surface having a plurality of features. Individual ones of the plurality of features are defined by one or more openings formed through a multi-layer stack, and the multi-layer stack includes a chalcogen containing material. The methods further include flowing pulses of a first processing gas into the processing volume. Herein, the first processing gas includes a silicon precursor and a nitrogen precursor. The methods further include igniting and maintaining a plasma of the first processing gas. The methods further include depositing a first silicon nitride layer onto the patterned surface of the substrate. Furthermore, the methods include depositing of a second silicon nitride layer on the first silicon nitride layer.

### CROSS-REFERENCE TO RELATED APPLICATIONS

This application claims the benefit to U.S. Provisional Application No. 62/855,597, filed May 31, 2019, which is incorporated by reference herein.

### BACKGROUND

### Field

Embodiments described herein generally relate to the field of semiconductor device manufacturing, and more particularly, to methods for forming a conformal silicon nitride encapsulation layer for phase-change memory random access memory (PCRAM) devices.

### Description of the Related Art

Non-volatile Memory (NVM) technologies play a fundamental role in the microelectronics industry. One such emerging NVM technology is Phase-Change Memory (PCM).

A typical PCM device includes an array of memory cells, where each memory cell includes a memory element and a selection element, such as an ovonic threshold switch (OTS). Commonly, the memory element is formed of a chalcogenide alloy which is electrically switched between an amorphous state and a crystalline state, or between different detectable states of local order across a spectrum between a completely amorphous state and a completely crystalline state. Commonly, the individual memory cells, of the array of memory cells, are spaced apart from one another and functionally isolated by a dielectric material disposed therebetween. The dielectric material prevents cell-to-cell interference, e.g., cross-talk, between adjacently disposed memory cells. Typically, the dielectric material includes an encapsulation layer which is used to line the walls of openings disposed between individual memory cells. The encapsulation layer protects the phase change and OTS materials from moisture and oxygen damage. Unfortunately, conventional methods of depositing encapsulation layers with PECVD (Plasma Enhanced Chemical Vapor Deposition) methods onto surfaces of a PCRAM memory cell may not be able to achieve the required conformality for a next generation PCRAM node with sufficient film coverage at the trench bottom. Plasma Enhanced Atomic layer deposition (PEALD) may achieve desired conformality but causes undesirable loss of the chalcogenide materials due to plasma induced damage.

Accordingly, there is a need in the art for improved methods of forming encapsulation layers on PCM devices.

### SUMMARY

Embodiments described herein generally relate to methods of forming encapsulation layers for use in phase change memory (PCM) devices. More specifically, embodiments of the present disclosure relate to methods of forming conformal silicon-nitride layers by pulsing processing gases during a PECVD process. In addition, the methods herein provide conformal silicon-nitride layers with enhanced conformality at a relatively low temperature and relatively low RF power, when compared to conventional plasma enhanced chemical vapor deposition (PECVD) methods. Furthermore, the methods herein further provide a multi-operation process including depositing a first silicon-nitride layer by a PECVD process, such as that described herein. Further, a second silicon-nitride layer is deposited by PEALD on the PECVD film to achieve the desired conformality and hermeticity. In some examples, the PECVD process or the PEALD process occur at a substrate temperature below 280° C.

In one embodiment, a method of processing a substrate includes positioning a substrate in a processing volume of a processing chamber. The substrate includes a patterned surface having a plurality of features. Individual ones of the plurality of features are defined by one or more openings formed through a multi-layer stack, and the multi-layer stack includes a chalcogen containing material. The method further includes flowing pulses of a silicon precursor and a nitrogen precursor into the processing volume. The method further includes igniting a plasma of the silicon precursor and the nitrogen precursor. The method further includes depositing a first silicon nitride layer onto the patterned surface of the substrate.

In another embodiment, a method of processing a substrate includes positioning a substrate in a processing volume of a processing chamber. The substrate includes a patterned surface having a plurality of features. Individual ones of the plurality of features are defined by one or more openings formed through a multi-layer stack, and the multi-layer stack includes a chalcogen containing material. The substrate is maintained at a temperature below 280° C. The method further includes flowing pulses of a silicon precursor and a nitrogen precursor into the processing volume. The method further includes igniting the silicon precursor and the nitrogen precursor. The method further includes depositing a first silicon nitride layer onto the patterned surface of the substrate, wherein the first silicon nitride layer has a conformality of about 80 percent or more. The method further includes depositing a second silicon nitride layer on the first silicon nitride layer, comprising sequential cycles of exposing the substrate to a second silicon precursor and exposing the substrate to a second nitrogen precursor, igniting a plasma, and exposing the substrate to the plasma.

In another embodiment, a computer-readable medium having instructions stored thereon for performing a method of processing a substrate when executed by a processor is provided. The method includes positioning a substrate in a processing volume of a processing chamber. The substrate comprises a patterned surface having a plurality of features. Individual ones of the plurality of features are defined by one or more openings formed through a multi-layer stack, and the multi-layer stack includes a chalcogen containing material. The substrate is maintained at a temperature below 280° C. The method further includes flowing pulses of a silicon precursor and a nitrogen precursor into the processing volume. The method further includes generating a plasma of the silicon precursor and the nitrogen precursor. The method further includes depositing a first silicon nitride layer onto the patterned surface of the substrate, wherein the first silicon nitride layer has a conformality of about 80 percent or more.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, and may admit to other equally effective embodiments.

FIG. 1 is a schematic cross-sectional view of an exemplary processing chamber used to practice the methods set forth herein, according to one embodiment.

FIGS. 2A-2B schematically illustrate the flow of a processing gas and an RF power used to ignite and maintain a plasma, according to respective embodiments described herein.

FIG. 3 is a flowchart setting forth a method of forming a silicon nitride layer, according to one embodiment.

FIGS. 4A-4C schematically illustrate a substrate during the method set forth in FIG. 3, according to one embodiment.

FIG. 4D schematically illustrates a substrate during the method of forming a second silicon nitride layer via PEALD, according to one embodiment.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments herein generally relate to methods of forming encapsulation layers to be used to encapsulate memory cells of phase change memory (PCM) devices. Particularly, embodiments of the present disclosure relate to methods of forming conformal silicon-nitride layers by pulsing a processing gas during a PECVD process. Furthermore, the methods herein provide conformal silicon-nitride layers at temperatures less than 280° C., and relatively low RF power, when compared to conventional plasma enhanced chemical vapor deposition (PECVD) methods.

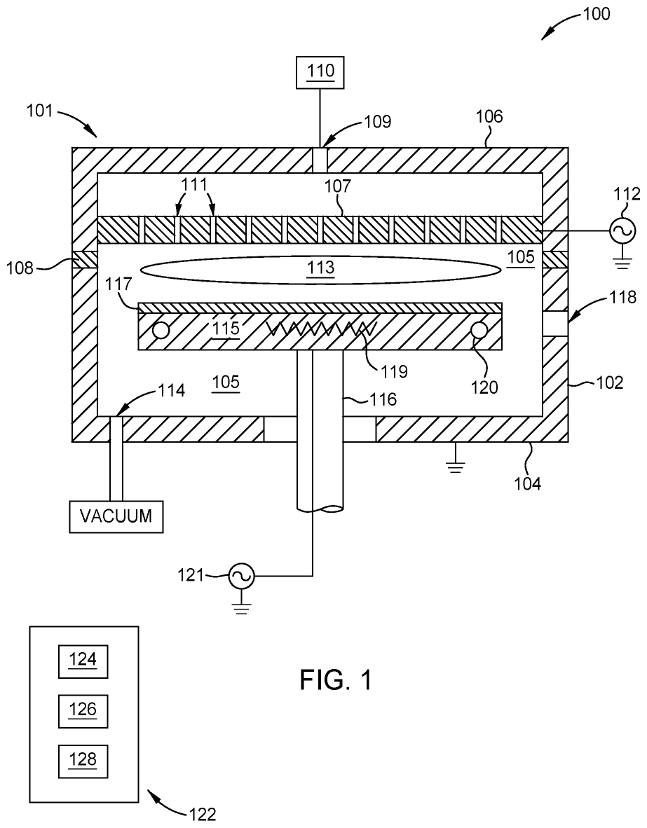

FIG. 1 is a schematic cross sectional view of an exemplary processing chamber used to practice the methods set forth herein, according to one embodiment. Other exemplary deposition chambers that may be used to practice the methods describe herein include an Ultima HDP CVD® system, or a Precision® PECVD system, or a Juniper® PEALD system among other systems, available from Applied Materials, Inc., of Santa Clara, Calif. as well as suitable deposition chambers from other manufacturers.

The processing chamber 100 is a processing chamber configured to perform PECVD, PEALD, and/or ALD. The processing chamber 100 is configured to ignite and maintain a plasma of processing gases through capacitive coupling. The processing chamber 100 includes a chamber lid assembly 101, one or more sidewalls 102, and a chamber base 104. The chamber lid assembly 101 includes a chamber lid 106, a showerhead 107 disposed in the chamber lid 106, and an electrically insulating ring 108, disposed between the chamber lid 106 and the one or more sidewalls 102. The showerhead 107, the one or more sidewalls 102, and the chamber base 104 together define a processing volume 105. A gas inlet 109, disposed through the chamber lid 106 is fluidly coupled to a gas source 110. The showerhead 107, having a plurality of openings 111 disposed therethrough, can be used to uniformly distribute processing gases from the gas source 110 into the processing volume 105. The showerhead 107 is electrically coupled to a first power supply 112, such as an RF power supply, which supplies power to ignite and maintain a plasma 113 of the processing gas through capacitive coupling therewith. Herein, the RF power has a frequency of from about 400 kHz and about 40 MHz, for example about 400 kHz or about 13.56 MHz. In other embodiments, the processing chamber 100 comprises an inductive plasma generator and the plasma is formed through inductively coupling an RF power to the processing gas.

The processing volume 105 is fluidly coupled to a vacuum source, such as to one or more dedicated vacuum pumps, through a vacuum outlet 114, which maintains the processing volume 105 at sub-atmospheric conditions and evacuates the processing gas and other gases therefrom. A substrate support 115, disposed in the processing volume 105, is disposed on a movable support shaft 116 sealingly extending through the chamber base 104, such as being surrounded by bellows (not shown) in the region below the chamber base 104. Herein, the processing chamber 100 is configured to facilitate transferring of a substrate 117 to and from the substrate support 115 through an opening 118 in one of the one or more sidewalls 102, which can be sealed with a door or a valve (not shown) during substrate processing.

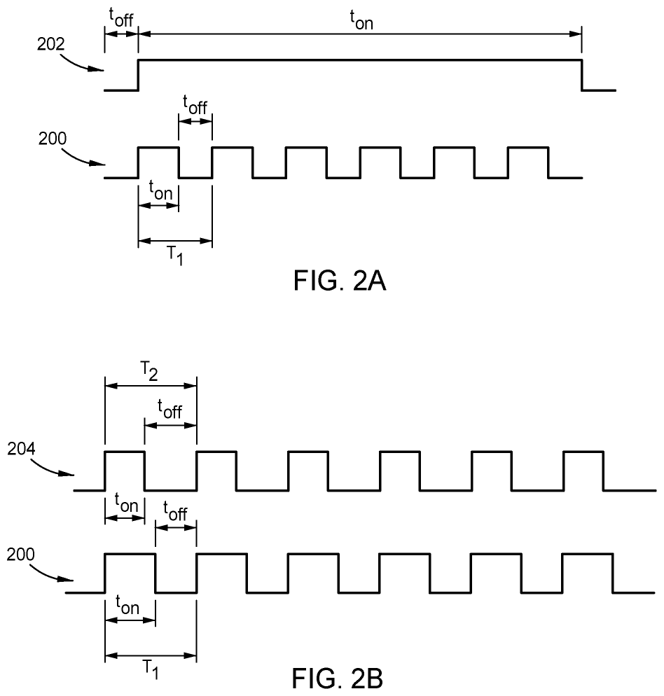

The substrate 117, disposed on the substrate support 115, is maintained at a desired processing temperature using one or both of a heater, such as a resistive heating element 119, and one or more cooling channels 120 disposed in the substrate support 115. The one or more cooling channels 120 are fluidly coupled to a coolant source (not shown), such as a modified water source having relatively high electrical resistance or a refrigerant source. In at least one embodiment, the substrate support 115 or one or more electrodes thereof is electrically coupled to a second power supply 121, such as a continuous wave (CW) RF power supply or a pulsed RF power supply, which supplies a bias voltage thereto. In some embodiments, one or both of the flow of the processing gas and the RF power supply are pulsed during processing of the substrate as further illustrated in FIGS. 2A and 2B.

The processing chamber 100 further includes a system controller 122 which is used to control the operation of the processing chamber 100 and implement the methods set forth herein. The system controller 122 includes a programmable central processing unit, herein the central processing unit (CPU) 124, that is operable with a memory 126 (e.g., non-volatile memory) and support circuits 128. The support circuits 128 are coupled to the CPU 124 and comprise cache, clock circuits, input/output subsystems, power supplies, and combinations thereof coupled to the various components of the processing chamber 100, to facilitate control thereof. The CPU 124 is one of any form of general purpose computer processor, such as a programmable logic controller (PLC), for controlling various components and sub-processors of the processing chamber 100. The memory 126, coupled to the CPU 124, is non-transitory and is typically one or more of readily available memories such as random access memory (RAM), read only memory (ROM), floppy disk drive, hard disk, or any other form of digital storage, local or remote.

Typically, the memory 126 is in the form of a computer-readable storage media containing instructions (e.g., non-volatile memory), that when executed by the CPU 124, facilitates the operation of the processing chamber 100. The instructions in the memory 126 are in the form of a program product such as a program that implements the methods of the present disclosure. The program code may conform to any one of a number of different programming languages. In one example, the disclosure may be implemented as a program product stored on computer-readable storage media for use with a computer system. The program(s) of the program product define functions of the embodiments (including the methods described herein).

FIGS. 2A-2B schematically illustrate the pulsed flow of a processing gas into a processing volume of a processing chamber, such as the processing chamber described in FIG. 1.

In FIG. 2A a continuous RF power 202 is used to ignite and maintain a plasma of the pulsed processing gas flow 200. Here, each pulse cycle of the processing gas flow 200 has a duration of T₂ with an on-time duration tₒₙ where a valve controlling the flow of the processing gas into the processing chamber is open and an off-time duration t_{off} where the valve controlling the flow of the processing gas is closed. In some embodiments, the pulse cycle time Ti has a duration of about 20 seconds or less, such as in the range of from about 0.001 seconds to about 20 seconds, such as from about 0.1 seconds to about 15 seconds, such as from about 0.5 seconds to about 12.5 seconds, such as from about 0.75 seconds to about 10 seconds. Furthermore, each of on cycles has an on-time duration tₒₙ of about 10 seconds or less, such as about 7.5 seconds or less, such as about 5 seconds or less, such as about 2.5 seconds or less, such as about 1 second or less, or for example as about 0.5 seconds or less. The on-time duty cycle of the flow pulses is from about 5% to about 95%, such as from about 10% to about 90%, such as from about 15% to about 85%, such as from about 20% to about 80%, of the pulse cycle time Ti. In further embodiments, the duration time t_{off} where the gas flow of the processing gas is off is from about 0.001 seconds to 10 seconds, such as from about 0.05 seconds to 7.5 seconds, such as from about 0.2 seconds to about 5 seconds, such as from about 0.3 seconds to about 2.5 seconds, such as from about 0.4 seconds to about 2 seconds, such as from about 0.5 seconds to about 1 second. The processing gas can be a mixture of at least two gases, such as a first gas (e.g., a silicon precursor) and a second gas (e.g., a nitrogen precursor). In some embodiments, the first gas and the second gas flow simultaneously, in pulses or continuously, at a same on-time duration tₒₙ, at a same off-time duration t_{off}, and/or at a same on-time duty cycle of the flow pulses. In another embodiment, the first gas flows continuously at a tₒₙ¹ time and the second gas flows in pulses at a tₒₙ² time, where tₒₙ² time is lower than tₒₙ¹ time and/or overlapping, not overlapping, partially overlapping with tₒₙ¹.

FIG. 2B illustrates an embodiment where both the processing gas flow 200 and the RF power 204 used to ignite and maintain a plasma of the processing gas are pulsed. While the processing gas is flowing in pulses as described above, an RF power 204 used to ignite and maintain the plasma is pulsed, where the pulses include a plurality of on cycles and off cycles. Here, each on cycle has an on-time duration tₒₙ and each off cycle has an off-time duration t_{off}, where each (tₒₙ+t_{off}) equal a total duration time T₂. Herein, the total duration time T₂ is from about 0.001 seconds to about 40 seconds, such as from about 0.1 seconds to about 35 seconds, such as from about 0.5 seconds to about 30 seconds, such as from about 0.75 seconds to about 25 seconds, such as from about 1 second to about 20 seconds. Furthermore, each of the on cycles has a duration time tₒₙ of less than about 40 seconds, such as about less than about 30 seconds, such as less than about 20 seconds, less than about 10 seconds, less than about 5 seconds, less than about 0.05 seconds. The on-time duty cycle of the pulses is from about 5% to about 95%, such as from about 10% to about 90%, such as from about 15% to about 85%, such as from about 20% to about 80%, of the total duty cycle time. In further embodiments, the off-time duration t_{off} where the RF power is off is of less than about 40 seconds, such as about less than about 30 seconds, such as less than about 20 seconds, less than about 10 seconds, less than about 5 seconds, less than about 0.05 seconds. In some embodiments, the pulse gas flow tₒₙ and the RF pulse tₒₙ have the same duration and run concurrently. In other embodiments, the on time of the pulse gas flow and the on time of the RF pulse are different and partially overlap or do not overlap in time.

In some examples, a pulsed process gas flow may be established by continuously flowing an inert or carrier gas into the chamber, but pulsing the flow of deposition (e.g., reactive) precursor gases. In such an example, the continued flow of the inert or carrier gas facilitates maintenance of a plasma within the process chamber, while the pulsing of deposition precursor achieves benefits disclosed herein. In one example which can be combined with other examples herein, the tₒₙ and the t_{off} of each individual deposition precursor may be substantially the same and overlapping during a PECVD process.

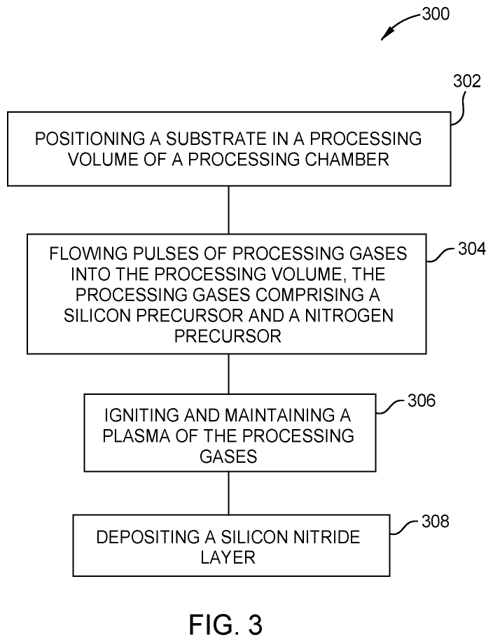

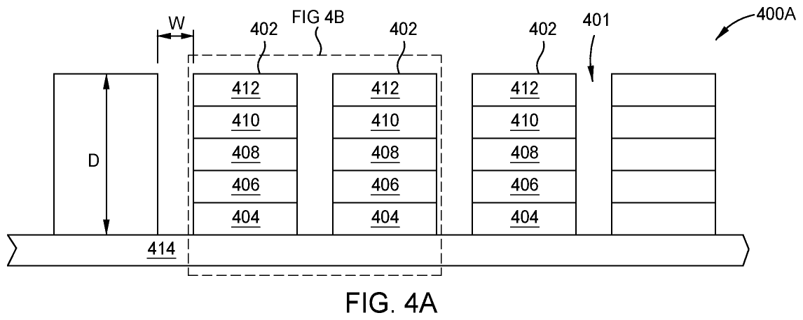

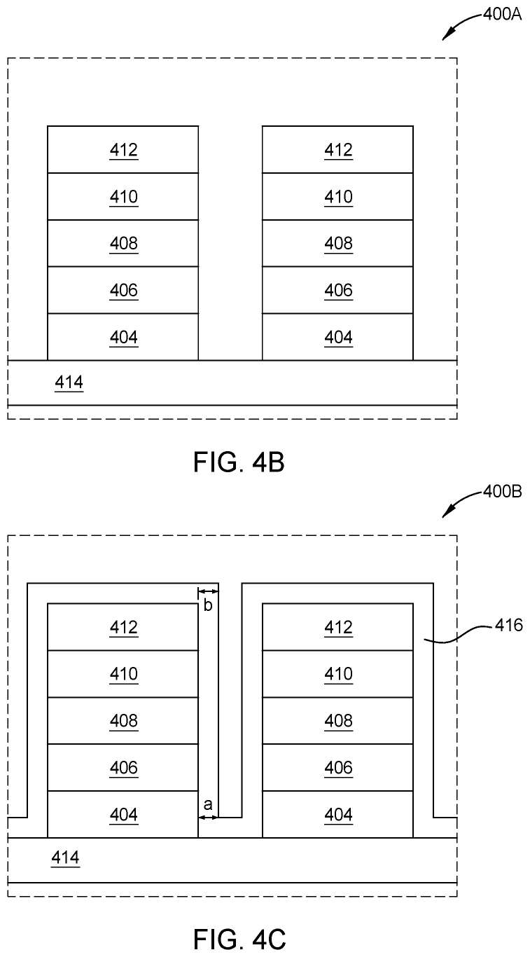

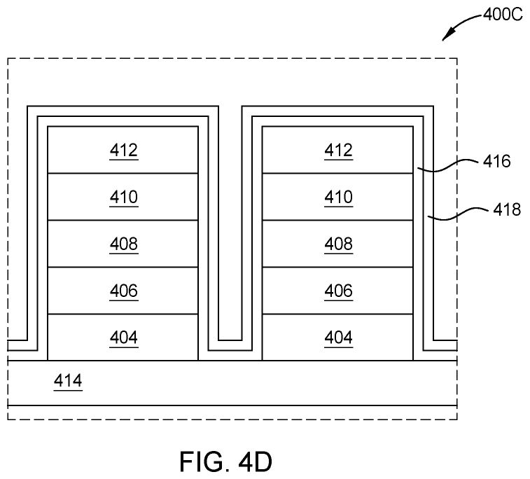

FIG. 3 is a flowchart setting forth a method 300 of forming a silicon nitride layer, according to one embodiment. FIGS. 4A-4C illustrate a substrate during the method 300 set forth in FIG. 3, according to one embodiment. FIG. 4D illustrates a substrate during the method of forming a second silicon nitride layer via PEALD.

In block 302, the method 300 includes positioning a patterned substrate 400A in a processing volume of a processing chamber, such as the processing chamber 100 described in FIG. 1. Here, the patterned substrate 400A includes a substrate 414, such as a silicon wafer, having a plurality of memory cells, such as the plurality of features 402 disposed thereon. The plurality of features 402 are formed of a multi-layer stack, where individual ones of the plurality of features 402 are defined by openings 401 formed through the multi-layer stack. The multi-layer stack includes a first electrode layer 404, a first chalcogen-containing layer 406 disposed on the first electrode layer 404, a second electrode layer 408 disposed on the first chalcogen-containing layer 406, a second chalcogen-containing layer 410 disposed on the second electrode layer 408, and a third electrode layer 412 disposed on the second chalcogen-containing layer 410.

Herein, a “chalcogenide alloy” is any material comprising at least one of a group 16 element of the Periodic Table, such as sulfur, selenium, tellurium, or a combination thereof, and/or at least one of a group 14 or group 15 element such as carbon (C) silicon (Si), germanium (Ge), tin (Sn), lead (Pb), nitrogen (N), phosphorus (P), arsenic (As), antimony (Sb), or bismuth (Bi), of the Periodic Table.

The openings 401 formed through the multilayer stack to define the plurality of features 402 have a width W of about 100 nm or less, such as about 90 nm or less, about 70 nm or less, about 60 nm or less, about 50 nm or less, for example about 20 nm or less. In some embodiments, an aspect ratio (the ratio of the depth D of the opening 401 to the width W of the opening 401) is in a range from about 4:1 to about 40:1, such as from about 5:1 to about 15:1, from about 7:1 to about 25:1, such as about 10:1 or more, for example. In at least one embodiment, individual ones of the plurality of openings 401 have an aspect ratio of 10:1 or more and a width W of 20 nm or less.

In block 304, the method 300 includes flowing in pulses of a processing gas into the processing volume. Herein, the processing gas comprises a silicon precursor and a nitrogen precursor. Suitable silicon precursors include silane (SiH₄), trisilylamine (TSA, N(SiH₃)₃), neopentasilane (NPS, (SiH₃)₄Si), iodosilanes, bromosilanes, alkyl-aminosilanes (e.g., SiH(N(CH₃)₂)₃, (SiH₂(NHₜBu)₂), C₉H₂₉N₃Si₃, C₆H₁₇NSi, C₉H₂₅N₃Si, C₈H₂₂N₂Si), or a combination thereof. Suitable nitrogen precursors include nitrogen gas (N₂), ammonia (NH₃), hydrazine (N₂H₄), or a combination thereof. The processing gas may also include a carrier gas, such as an inert gas such as argon or helium.

Suitable iodosilanes are SiI₄, Si₂I₆, SiH₂I₂, Si₃I₈, SiH₃I, and combinations thereof. Suitable bromosilanes are SiBr₄, Si₂Br₆, SiH₂Br₂, Si₃Br₈, SiH₃Br, and combinations thereof. In some embodiments, the silicon precursor is substantially free of fluorine or chlorine atoms to avoid damage to the phase change or OTS materials of the memory cell by exposure thereto. In at least one embodiment, a silicon halide precursor which includes substantially no chlorine atoms nor fluorine atoms consists of less than about 1%, such as less than about 0.5%, such as less than about 0.1% of halogen atoms on an atomic count basis.

Flow rates of the processing gases into the processing volume are dependent on the size of a substrate to be processed and/or the chamber architecture. For example, for a chamber sized to process a 300 mm diameter substrate, the flow rate of the silicon precursor during the on-time duration tₒₙ is in a range from about 5 sccm to about 1,000 sccm, such as from about 10 sccm to about 500 sccm, from about 25 sccm to about 250 sccm, such as about 50 sccm, for example.

The flow rate of the nitrogen precursor (e.g., NH₃) is from about 5 sccm to about 2,500 sccm, such as from about 10 sccm to about 2,000 sccm, such as from about 25 sccm to about 1,000 sccm, such as from about 50 sccm to about 250 sccm, such as for example about 100 sccm. In a chamber configured to process a 300 mm diameter substrate, the N₂ flow rate is from about 100 sccm to about 4,000 sccm, such as from about 250 sccm to about 3,000 sccm, such as from about 500 sccm to about 2,500 sccm, such as about 2,000 sccm, for example.

The combined flow rate of the silicon and the nitrogen precursors is from about 5 sccm to about 2,500 sccm, such as from about 10 sccm to about 2,000 sccm, such as from about 25 sccm to about 1,000 sccm, such as from about 50 sccm to about 250 sccm, such as for example about 100 sccm.

The optional carrier gas may be an inert gas, such as argon or helium. In at least one embodiment, the carrier gas flow rate is from about 100 sccm to about 5,000 sccm, such as from about 250 sccm to about 4,500 sccm, such as from about 500 sccm to about 4,000 sccm. The flow rate of the silicon precursor may be slower than the flow rate of the nitrogen precursor (and the carrier gas, leading to the processing gas having a low concentration of silicon precursor).

The method 300 further includes igniting a plasma of the processing gas in block 306 by applying an RF power to an electrode, such as a showerhead, of the processing chamber. The plasma activates the processing gas in the processing volume to form reactive species, such as radicals and ions, from the less reactive precursors forming the processing gas. Here, the applied RF power is continuous or pulsed. The plasma formed with one or both of the pulsed gas flow and pulsed RF powers described herein increases the ratio of neutral to ion species in the plasma. The increase in long-lived neutral species allows for diffusion into nanometer sized features, avoids electron shading effects, and increases migration of adsorbed species on the surface of the substrate, resulting in improved conformality. For example, in some embodiments, the activated species of the silicon precursor (e.g., TSA) have lower sticking coefficients and greater surface migration using the method 300 described above when compared to deposition methods using both continuous gas flow and continuous RF power. Beneficially, in combination with pulsing the processing gas, pulsing the RF power (e.g., RF power of about 250 Watts or less) increases the formation of radicals while simultaneously decreasing the formation of ions. Desirably, the radicals diffuse faster in the openings than the ions because the radicals sticking coefficient is lower than that of the ions sticking coefficient. In some embodiments, the pressure of the processing volume is less than about 15 Torr, such as from about 1 mTorr to about 15 Torr, to decrease gaseous molecular interactions or recombination. For example, in some embodiments the pressure of the processing volume is maintained from about 1 mTorr to about 15 Torr, such as from about 0.5 Torr to about 12 Torr, such as from about 1 Torr to about 10 Torr, such as from about 3 Torr, to about 8 Torr, such as 6 Torr, for example.

The RF power provided to the showerhead 107 can be dependent on the size of the substrate 117 and the chamber 100. For example, for a chamber sized to process a 300 mm diameter substrate, the RF power is about 250 Watts or less, such as about 200 Watts or less, such as about 150 Watts or less, such as about 100 Watts or less, such as about 75 Watts or less, such as about 50 Watts or less, such as about 25 Watts or less. The RF power provided herein can be scaled for chambers configured to process substrates of different sizes. For example, in some embodiments, the RF power is about 0.35 W/cm² (of substrate processing surface) or less, such as about 0.28 W/cm² or less, such as about 0.21 W/cm² or less, such as about 0.14 W/cm² or less, such as about 0.11 W/cm² or less, such as about 0.07 W/cm² or less, such as about 0.035 W/cm² or less. In further embodiment, the RF power has a frequency of from about 400 kHz and about 40 MHz, for example about 400 kHz or about 13.56 MHz.

The method 300 further includes depositing a first silicon nitride layer 416 onto the patterned surface of the substrate in block 308. FIGS. 4A-4B show a patterned surface of the substrate 414, and FIG. 4C shows a first silicon nitride layer 416, formed according to the method 300, deposited thereon. FIG. 4D shows a second silicon nitride layer 418 deposited conformally on the surface of the first silicon nitride, where the second silicon nitride layer 418 is formed according to a PEALD process.

In at least one embodiment, the method 300 includes maintaining the temperature of the substrate 414 at about 300° C. or less during deposition of the silicon nitride layer, such as about 200° C. or less, about 100° C. or less, or for example in a range from about 50° C. to about 300° C., such as from about 75° C. to about 250° C., from about 100° C. and about 200° C., or for example at about 80° C. The first silicon nitride layer 416 shown in FIGS. 4C-4D is a dielectric film having a thickness of about 1 Å to about 500 Å, or about 100 Å or less, such about 50 Å or less, for example 30 Å or less. The first silicon nitride layer 416 conforms to the underlying patterned surface of the substrate, herein the patterned surface of the substrate 414 and the features 402 disposed thereon, in order to provide uniform encapsulation of the features 402, resulting in formation of structure 400B (shown in FIG. 4C). The first silicon nitride layer 416 conforms to the underlying surface in order to provide uniform encapsulation of the PCM device and any contaminate particles disposed thereon.

The conformal nature of a film/layer is defined by the conformality of the film (e.g., the conformality of the first silicon nitride layer). The term “conformality” refers to the ratio of the thickness of a silicon nitride layer at the bottom side wall of the opening 401 to the thickness of the silicon nitride layer at the top of the opening 401 (as described in FIG. 4C, conformality is equal to a bottom thickness “a” divided by a top thickness “b”). As used in this regard, the term “conformal” means that the thickness of the silicon film is uniform across the patterned surface of the substrate 414. The term “substantially conformal” means that the thickness of the film does not vary by more than about 10%, such as about 5%, such as about 2%, such as about 1%, such as about 0.5% relative to the average thickness of the film. In at least one embodiment, the first silicon nitride layer 416 is deposited onto the patterned surface of the substrate 414, such that the first silicon nitride layer 416 is a conformal silicon nitride layer with a conformality of about 80% or greater, such as a conformality of about 90% to about 99.99%, such as from about 92.5% to about 97.5%.

In one example, block 308 occurs while maintaining the substrate at a temperature of less than about 280° C. By forming the first silicon nitride layer 416 at a temperature less than 280° C., while pulsing the processing gas, the conformality of the first silicon nitride layer 416 is improved as compared to conventional aspects. Furthermore, current leakage, etch rate, and density of the first silicon nitride layer 416 are also improved.

In some embodiments, the method 300 further includes depositing a second silicon nitride layer 418, on the first silicon nitride layer 416 using PEALD process to improve hermeticity. Generally, silicon nitride layers formed using a PEALD process have increased hermeticity when compared to silicon nitride layers formed using a PECVD process. Unfortunately, the PEALD process can cause undesirable damage to chalcogenide materials. Thus, in some embodiments, the first silicon nitride layer 416 is used to form a protective barrier to prevent ion damage to the chalcogenide materials of the PCM device which would otherwise occur if the PCM device was exposed to the PEALD process used to form the second silicon nitride layer 418.

To improve film quality, a plasma treatment may be performed. In one example, the plasma treatment facilitates removal of dangling bonds from the deposited film. In some embodiments, the method 300 further includes periodically plasma treating the first silicon nitride layer 416 during the deposition thereof. In those embodiments, the method 300 includes sequential repetitions of between about 5 cycles to about 100 cycles of depositing a portion of the first silicon nitride layer 416 and exposing the deposited portion of plasma treatment. For example, in one embodiment plasma treating an at least partially deposited first silicon nitride layer 416 includes flowing a treatment gas comprising nitrogen N₂ and He into the processing volume, igniting and maintaining a plasma of the treatment gas using an RF power from about 250 Watts to about 750 watts, and exposing the partially deposited silicon nitride layer 416 to the plasma treatment. In one embodiment, the substrate is exposed to the plasma treatment after every 5 pulses to 50 pulses of processing gas until the first silicon nitride layer has a thickness of about 10 Å to about 70 Å.

During the plasma treatment, the pressure in the processing volume is maintained from about 0.1 Torr to about 10 Torr, such as from about 1 Torr to about 3 Torr; an RF power of from about 50 Watts to about 1,500 Watts, such as from about 250 Watts to about 1,000 Watts, such as about 500 Watts, for example; an N₂ flow rate of from about 50 sccm to about 5,000 sccm, such as from about 250 sccm to about 4,000 sccm, such as from about 500 sccm to about 2,000 sccm; a gas carrier (e.g., He) flow rate of from about 50 sccm to about 10,000 sccm, such as from about 500 sccm to about 8,000 sccm, such as from about 1,000 sccm to about 6,000 sccm, such as from about 2,000 sccm to about 4,000 sccm; and/or an RF power of from about 50 Watts to about 1,500 Watts, such as from about 250 Watts to about 1,000 Watts, such as from about 500 Watts to about 750 Watts.

Here, forming the second silicon nitride layer 418 via PEALD process includes sequential cycles of exposing the substrate, and thus the first silicon nitride layer 416, to a silicon precursor in a gaseous phase before exposing the substrate to a nitrogen precursor in a gaseous phase, or vice versa, and exposing the substrate to a plasma to facilitate film growth. Typically, the processing volume 105 is purged using a purge gas, such as an inert gas, after flowing the silicon precursor and after flowing the nitrogen precursor thereinto. For example, a purge gas, such as argon, can be introduced into the processing chamber to purge the reaction zone or otherwise remove any residual reactive compound or reaction by-products from the reaction zone. Alternatively, the purge gas may flow continuously throughout the deposition process so that only the purge gas flows during the time delay between pulses of the precursors. The precursors can be alternatively pulsed until a film thickness is formed on the surface of the first silicon nitride layer 416. Here, the silicon and nitrogen precursors used to form the second silicon nitride layer 418 are selected from those described above in block 304 of the method 300 and may be the same or different as the precursors used to form the first silicon nitride layer 416.

In one embodiment, the second silicon nitride layer 418 is deposited in the same chamber as the first silicon nitride layer 416. In another embodiment, the second silicon nitride layer 418 is deposited in a different chamber than the first silicon nitride layer 416. In some embodiments, the substrate is maintained at a temperature of from about 25° C. to about 300° C., such as from about 100° C. to about 275° C., such as from about 150° C. to about 250° C., or at about 300° C. or less, such as about 275° C. or less, for example about 250° C. or less. In at least one embodiment, the processing volume is maintained at a pressure from about 0.1 Torr to about 100 Torr, such as about 1 Torr to about 50 Torr, for example about 2 Torr to about 30 Torr.

In at least one embodiment, the second silicon nitride layer 418 is deposited using a PEALD process where plasma is required to grow, and treat the silicon nitride film with respect to forming the first silicon nitride layer 416. Here, the first and second silicon nitride layers 416 and 418 are each deposited to a thickness of about 1 Å to about 100 Å, such as about 5 Å to about 75 Å, about 10 Å to about 50 Å, for example about 15 Å to about 30 Å. Here, the second silicon nitride layer 418 has a conformality of at least 70% or more, such as 80% or more, for example 90% or more.

The methods described herein provide for the deposition of encapsulation layers for use in phase change memory (PCM) devices. More specifically, embodiments of the present disclosure provides methods of forming conformal silicon-nitride layers at a relatively low temperature and relatively low RF power, when compared to conventional plasma enhanced chemical vapor deposition (PECVD) methods, by flowing in pulses a processing gas during a PECVD process. Beneficially, the methods herein provide conformal layers deposition of the silicon nitride encapsulation to the patterned surface of the substrate with minimal damage to the materials of a PCM device.

Additionally, the encapsulation layers disclosed herein are deposited at a relatively low temperature (e.g., less than about 280° C.), yet the encapsulation layer is stable even at higher temperatures (e.g., up to about 500° C.) so as not to be damaged during thermal anneals. Also, the disclosed encapsulation layers desorb minimal or no hydrogen, oxygen, or water vapor, and exhibit high hermeticity. Moreover, the methods herein provide conformal deposition of silicon nitride encapsulation layers with minimal or substantially no damage to the chalcogenide alloys used to form the memory element and OTS of the memory cell.

While the foregoing is directed to embodiments of the present disclosure, other and further embodiments of the disclosure may be devised without departing from the basic scope thereof, and the scope thereof is determined by the claims that follow.

What is claimed is:

1. A method of processing a substrate, comprising:
positioning a substrate in a processing volume of a processing chamber, the substrate comprising a patterned surface having a plurality of features, wherein individual ones of the plurality of features are defined by one or more openings formed through a multi-layer stack, wherein at least one layer of the multi-layer stack comprises a chalcogen containing material;
flowing pulses of a silicon precursor and a nitrogen precursor into the processing volume;
igniting a plasma of the silicon precursor and the nitrogen precursor; and
depositing a first silicon nitride layer onto the patterned surface of the substrate.

2. The method of claim 1, wherein the silicon precursor and the nitrogen precursor are introduced to the processing volume at the same duty cycle.

3. The method of claim 2, wherein the silicon precursor and the nitrogen precursor flow simultaneously.

4. The method of claim 1, wherein one of the silicon precursor and the nitrogen precursor has a greater duty cycle than the other of the silicon precursor and the nitrogen precursor.

5. The method of claim 1, wherein each pulse cycle of pulses of the nitrogen precursor or the silicon precursor has a cycle time of 20 seconds or less and each on time of a cycle is 10 seconds or less.

6. The method of claim 1, wherein an RF power used to ignite the plasma of the silicon precursor and the nitrogen precursor is about 0.035 Watts per cm² of substrate processing surface (W/cm²) or less.

7. The method of claim 1, further comprising maintaining the substrate at a temperature below 280° C.

8. The method of claim 1, wherein the silicon precursor comprises silane, trisilylamine, neopentasilane, silanes halides, alkyl-aminosilanes, or a combination thereof.

9. The method of claim 1, wherein the nitrogen precursor comprises nitrogen gas, ammonia, hydrazine, or a combination thereof.

10. The method of claim 1, wherein the first silicon nitride layer is deposited to a thickness of about 30 Å or less, and has a conformality of about 80% or more.

11. The method of claim 10, further comprising depositing a second silicon nitride layer on the first silicon nitride layer during a plasma enhanced atomic layer deposition (PEALD) process.

12. The method of claim 11, wherein the PEALD process comprises sequential cycles of exposing the substrate to a silicon precursor, exposing the substrate to a nitrogen precursor, and exposing the substrate to a plasma.

13. The method of claim 12, wherein the second silicon nitride layer is deposited to a thickness of about 15 Å to about 30 Å, and has a percent conformality of more than 80 percent.

14. A method of processing a substrate, comprising:
positioning a substrate in a processing volume of a processing chamber, the substrate comprising a patterned surface having a plurality of features, wherein individual ones of the plurality of features are defined by one or more openings formed through a multi-layer stack, wherein at least one layer of the multi-layer stack comprises a chalcogen containing material, and wherein the substrate is maintained at a temperature below 280° C.;
flowing pulses of a silicon precursor and a nitrogen precursor into the processing volume;
igniting a plasma of the silicon precursor and the nitrogen precursor;
depositing a first silicon nitride layer onto the patterned surface of the substrate, wherein the first silicon nitride layer has a conformality of about 80 percent or more; and
depositing a second silicon nitride layer on the first silicon nitride layer, comprising sequential cycles of exposing the substrate to a second silicon precursor and exposing the substrate to a second nitrogen precursor, igniting a plasma, and exposing the substrate to the plasma.

15. The method of claim 14, further comprising:
purging the processing volume with a purge gas after exposing the substrate to the silicon precursor and after exposing the substrate to the nitrogen precursor, wherein the purge gas is an inert gas.

16. A computer-readable medium having instructions stored thereon for performing a method of processing a substrate when executed by a processor, the method comprising:
positioning a substrate in a processing volume of a processing chamber, the substrate comprising a patterned surface having a plurality of features, wherein individual ones of the plurality of features are defined by one or more openings formed through a multi-layer stack, wherein at least one layer of the multi-layer stack comprises a chalcogen containing material, and wherein the substrate is maintained at a temperature below 280° C.;
flowing pulses of a silicon precursor and a nitrogen precursor into the processing volume;
igniting a plasma of the silicon precursor and the nitrogen precursor; and
depositing a first silicon nitride layer onto the patterned surface of the substrate, wherein the first silicon nitride layer has a conformality of about 80 percent or more.

17. The computer-readable medium of claim 16, wherein the silicon precursor and the nitrogen precursor have the same duty cycles.

18. The computer-readable medium of claim 16, wherein each pulse cycle of pulses of the silicon precursor and the nitrogen precursor has a cycle time of 20 seconds or less and each on time of a cycle is 10 seconds or less.

19. The computer-readable medium of claim 16, further comprising instructions for depositing a second silicon nitride layer deposited on the first silicon nitride layer using a plasma enhanced atomic layer deposition (PEALD) process.

20. The computer-readable medium of claim 19, further comprising instructions for purging the processing volume between exposing the substrate to the plasma formed of the silicon precursor and exposing the substrate to the plasma formed of the nitrogen precursor during the PEALD process.
